(19) United States
(12) Patent Application Publication
(10) Pub. No.: US 2026/0052682 A1
(43) Pub. Date: Feb. 19, 2026

(54) SEMICONDUCTOR MEMORY DEVICE

(71) Applicant: SAMSUNG ELECTRONICS CO., LTD., SUWON-SI (KR)

(72) Inventors: Kyo-Seon CHOI, Suwon-si (KR); Chae Seok KWAK, Suwon-si (KR); Hyeon Tae KIM, Suwon-si (KR); Jul Pin PARK, Suwon-si (KR)

(21) Appl. No.: 19/181,546

(22) Filed: Apr. 17, 2025

(30) Foreign Application Priority Data
Aug. 19, 2024 (KR) 10-2024-0110488

(51) Int. Cl. H10B 12/00

(52) U.S. Cl. CPC H10B 12/50

(57) ABSTRACT

A semiconductor memory device including: a peri-active substrate which includes a peri-semiconductor film and a peri-semiconductor separation film, wherein the peri-active substrate overlaps a substrate; a first connecting wiring structure disposed between the substrate and the peri-active substrate; a peri-gate structure disposed on the peri-semiconductor film; a peri-contact plug connected to the peri-gate structure; a peri-wiring line connected to the peri-contact plug; and a peri-connecting penetration plug which penetrates the peri-semiconductor separation film, and connects the first connecting wiring structure and the peri-wiring line, wherein the peri-active substrate includes a first surface and a second surface, each of the first surface of the peri-active substrate and the second surface of the peri-active substrate is formed by the peri-semiconductor film and the peri-semiconductor separation film, the peri-wiring line and the peri-gate structure are disposed on the first surface, and the first surface formed by the peri-semiconductor separation film is convex.

### CROSS-REFERENCE TO RELATED APPLICATION

This application claims priority under 35 U.S.C. § 119 to Korean Patent Application No. 10-2024-0110488 filed on Aug. 19, 2024 in the Korean Intellectual Property Office, the disclosure of which is incorporated by reference herein in its entirety.

### TECHNICAL FIELD

The present disclosure relates to a semiconductor memory device.

### DESCRIPTION OF THE RELATED ART

To meet consumer demands for high performance and low-cost semiconductor memory devices, increasing the degree of integration is essential. Since integration level significantly influences product pricing, particularly in semiconductor memory devices, achieving higher integration is an important requirement.

For two-dimensional or planar semiconductor memory devices, the degree of integration is primarily determined by the area occupied by unit memory cells and is heavily influenced by the level of fine patterning technology. However, miniaturizing patterns requires ultra-expensive equipment, which imposes limitations on increasing the integration of two-dimensional memory devices. To address this, a semiconductor memory device has been proposed in which memory cells and the logic transistors controlling them are stacked vertically.

### SUMMARY

Embodiments of the present disclosure provide a semiconductor memory device having improved integration density and electrical performance.

According to an embodiment of the present disclosure, there is provided a semiconductor memory device including: a peri-active substrate which includes a peri-semiconductor film and a peri-semiconductor separation film, wherein the peri-active substrate overlaps a substrate in a first direction; a first connecting wiring structure which is disposed between the substrate and the peri-active substrate; a peri-gate structure which is disposed on the peri-semiconductor film; a peri-contact plug which is connected to the peri-gate structure; a peri-wiring line which is connected to the peri-contact plug; and a peri-connecting penetration plug which penetrates the peri-semiconductor separation film, and connects the first connecting wiring structure and the peri-wiring line, wherein the peri-active substrate includes a first surface and a second surface that are opposite to each other in the first direction, each of the first surface of the peri-active substrate and the second surface of the peri-active substrate is formed by the peri-semiconductor film and the peri-semiconductor separation film, the peri-wiring line and the peri-gate structure are disposed on the first surface of the peri-active substrate, and the first surface of the peri-active substrate formed by the peri-semiconductor separation film is convex.

According to an embodiment of the present disclosure, there is provided a semiconductor memory device including: a peri-active substrate which includes a peri-semiconductor film and a peri-semiconductor separation film, wherein the peri-active substrate overlaps a substrate in a first direction; a connecting wiring structure which is disposed between the substrate and the peri-active substrate; a peri-gate structure which is disposed on the peri-semiconductor film; a peri-contact plug which is connected to the peri-gate structure; a peri-wiring line which is connected to the peri-contact plug; and a peri-connecting penetration plug which penetrates the peri-semiconductor separation film, and connects the connecting wiring structure and the peri-wiring line, wherein the peri-active substrate includes a first surface and a second surface that are opposite to each other in the first direction, each of the first surface of the peri-active substrate and the second surface of the peri-active substrate is formed by the peri-semiconductor film and the peri-semiconductor separation film, and a thickness of the peri-semiconductor separation film in the first direction is greater than a thickness of the peri-semiconductor film in the first direction.

According to an embodiment of the present disclosure, there is provided a semiconductor memory device including: a peri-active substrate, which is spaced apart from a substrate in a first direction, and includes a peri-semiconductor film and a peri-semiconductor separation film, a thickness of the peri-semiconductor separation film in the first direction being greater than a thickness of the peri-semiconductor film in the first direction; a peri-element separation film which is disposed inside the peri-semiconductor film; a data storage pattern which is disposed between the substrate and the peri-active substrate; a connecting wiring structure which is disposed between the substrate and the peri-active substrate, and connected to the data storage pattern; a peri-gate structure which is disposed on the peri-semiconductor film; a peri-contact plug which is connected to the peri-gate structure; a peri-wiring line which is connected to the peri-contact plug; and a peri-connecting penetration plug which penetrates the peri-semiconductor separation film, and connects the connecting wiring structure and the peri-wiring line, wherein the peri-active substrate includes a first surface and a second surface that are opposite to each other in the first direction, the peri-wiring line and the peri-gate structure are disposed on the first surface of the peri-active substrate, the first surface of the peri-active substrate formed by the peri-semiconductor separation film is convex, a thickness of the peri-element separation film in the first direction is less than the thickness of the peri-semiconductor separation film in the first direction, and a width of the peri-element separation film in a second direction is less than a width of the peri-semiconductor separation film in the second direction.

### BRIEF DESCRIPTION OF THE DRAWINGS

The above and other features of the present disclosure will be more clearly understood through a detailed description of illustrative embodiments, accompanied by the attached drawings.

FIG. 1 is a diagram for explaining a semiconductor memory device according to some embodiments.

FIG. 2 is a diagram showing an enlarged view of a portion P of FIG. 1.

FIG. 3 is a diagram showing an enlarged view of a portion Q of FIG. 1.

FIGS. 4, 5 and 6 are diagrams for explaining a semiconductor memory device according to some embodiments.

FIG. 7 is a diagram for explaining a semiconductor memory device according to some embodiments.

FIG. 8 is a diagram for explaining a semiconductor memory device according to some embodiments.

FIG. 9 is a diagram for explaining a semiconductor memory device according to some embodiments.

FIG. 10 is a diagram for explaining a semiconductor memory device according to some embodiments.

FIG. 11 is a diagram for explaining a semiconductor memory device according to some embodiments.

FIGS. 12, 13, 14, 15, 16, 17, 18, 19, 20 and 21 are intermediate stage diagrams for describing a method for manufacturing a semiconductor memory device according to some embodiments.

### DETAILED DESCRIPTION OF THE EMBODIMENTS

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section.

The present disclosure pertains to a semiconductor memory device that enhances integration density and electrical performance. It features a peri-active substrate with a peri-semiconductor film and a convex-shaped peri-semiconductor separation film, separated vertically from the main substrate. This design supports efficient stacking and includes elements like a peri-gate structure, peri-contact plug, and peri-wiring line for optimized electrical connectivity and signal flow.

The semiconductor memory device also integrates advanced materials and configurations, such as a peri-element separation film for enhanced isolation and functionality. It supports high-density data storage patterns, including capacitors or variable resistance elements, through improved wiring and structural designs. By addressing the limitations of traditional two-dimensional memory devices, this disclosure enables cost-effective, high-performance solutions for modern semiconductor memory.

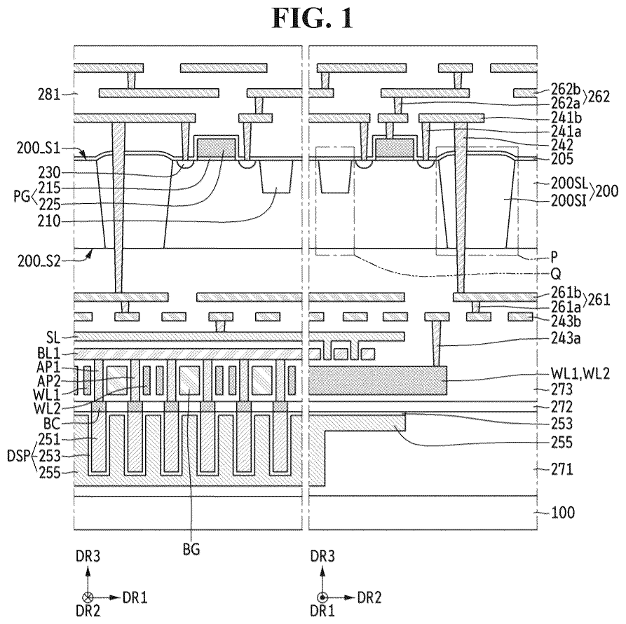

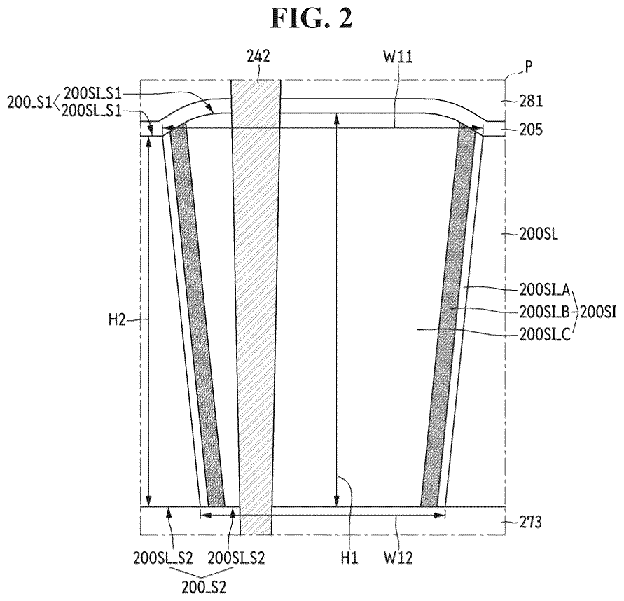

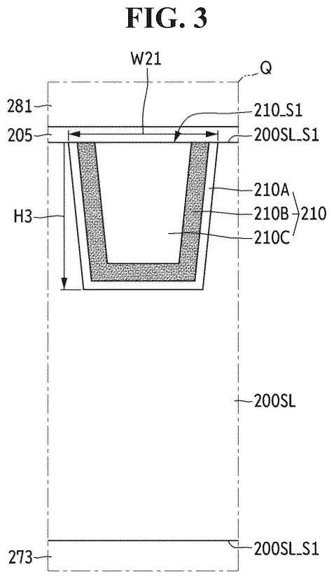

FIG. 1 is a diagram for explaining a semiconductor memory device according to some embodiments. FIG. 2 is a diagram showing an enlarged view of a portion P of FIG. 1. FIG. 3 is a diagram showing an enlarged view of a portion Q of FIG. 1.

Referring to FIGS. 1 to 3, the semiconductor memory device according to some embodiments may include a peri-active substrate 200, a peri-gate structure PG, a first connecting wiring structure 261, a second connecting wiring structure 262, a peri-contact plug 241a, a peri-wiring line 241b, and a peri-connecting penetration plug 242.

Substrate 100 may be a silicon substrate or may include other materials, for example, silicon germanium, indium antimonide, lead telluride, indium arsenide, indium phosphide, gallium arsenide or gallium antimonide.

A data storage pattern DSP may be disposed on the substrate 100. The data storage pattern DSP may be arranged in the form of a matrix along a first direction DR1 and a second direction DR2.

Here, the first direction DR1 and the second direction DR2 may be perpendicular to a third direction DR3. The first direction DR1 may intersect the second direction DR2. For example, the third direction DR3 may be a thickness direction of the substrate 100. The first direction DR1 and the second direction DR2 may be parallel to an upper surface of the substrate 100.

As an example, the data storage patterns DSP may be capacitors. The data storage patterns DSP may include a capacitor dielectric film 253 interposed between a storage electrode 251 and a plate electrode 255. The storage electrode 251 may have various shapes such as a circle, an ellipse, a rectangle, a square, a rhombus or a hexagon from a planar viewpoint.

Each of the storage electrode 251 and the plate electrode 255 may include, for example, at least one of a conductive semiconductor material, a conductive metal nitride, a conductive metal silicon nitride, a metal carbonitride, a conductive metal silicide, a conductive metal oxide, and a metal. The capacitor dielectric film 253 may include at least one of a ferroelectric material, an antiferroelectric material, and a paraelectric material. For example, the capacitor dielectric film 253 may include one of the ferroelectric material, the antiferroelectric material, the paraelectric material, a combination of the ferroelectric and antiferroelectric materials, a combination of the ferroelectric and paraelectric materials, a combination of paraelectric and antiferroelectric materials, and a combination of the ferroelectric material, the antiferroelectric material and the paraelectric material.

In contrast, the data storage patterns DSP may be variable resistance patterns capable of switching between two resistance states in response to electrical pulses applied to the memory element. For example, the data storage patterns DSP may include phase-change materials whose crystalline states vary with the applied current, as well as perovskite compounds, transition metal oxides, magnetic materials, ferromagnetic materials or antiferromagnetic materials.

Contact patterns BC may be disposed on the storage electrode 251. The contact patterns BC may be connected to each of a first active pattern AP1 and a second active pattern AP2. Each contact pattern BC may have various shapes such as a circle, an ellipse, a rectangle, a square, a rhombus or a hexagon from the planar viewpoint.

The contact patterns BC may include a conductive material. The contact patterns BC may include at least one of doped polysilicon, a conductive metal nitride, a conductive metal silicon nitride, a metal carbonitride, a conductive metal silicide, a conductive metal oxide, a two-dimensional material, and a metal.

The first active patterns AP1 and the second active patterns AP2 may be disposed on the data storage pattern DSP. The data storage patterns DSP may be disposed between the first active pattern AP1 and the substrate 100. The data storage patterns DSP may be disposed between the second active pattern AP2 and the substrate 100. The first active patterns AP1 and the second active patterns AP2 may be arranged alternately along the first direction DR1. The first and second active patterns AP1 and AP2 may be arranged two-dimensionally along the first direction DR1 and the second direction DR2.

For example, each of the first active pattern AP1 and the second active pattern AP2 may be made of a single crystal semiconductor material. As an example, each of the first active pattern AP1 and the second active pattern AP2 may be made of single crystal silicon.

A back gate electrode BG may be disposed on the data storage pattern DSP. The back gate electrode BG may be disposed on the contact pattern BC. The data storage pattern DSP may be disposed between the back gate electrode BG and the substrate 100.

The back gate electrode BG may extend in the second direction DR2. The back gate electrodes BG may be spaced apart from each other in the first direction DR1. The back gate electrodes BG may be spaced apart at regular intervals.

Each back gate electrode BG may be disposed between the first active pattern AP1 and the second active pattern AP2 that are adjacent to each other in the first direction DR1. In other words, a first active pattern AP1 may be disposed on one side of each back gate electrode BG, and a second active pattern AP2 may be disposed on the other side of each back gate electrode BG. For example, a first active pattern AP1 may be disposed on a first side of each back gate electrode BG, and a second active pattern AP2 may be disposed on a second side of each back gate electrode BG.

The first active pattern AP1 may be disposed between the first word line WL1 and the back gate electrode BG. The second active pattern AP2 may be disposed between the second word line WL2 and the back gate electrode BG. A pair of a first word line WL1 and a second word line WL2 may be disposed between the back gate electrodes BG that are adjacent to each other in the first direction DR1.

The back gate electrode BG may include a conductive material, and may include, for example, at least one of a doped polysilicon, a conductive metal nitride, a conductive metal silicon nitride, a metal carbonitride, a conductive metal silicide, a conductive metal oxide, a two-dimensional material, and a metal.

A back gate insulating film may be disposed between the back gate electrode BG and the first active pattern AP1, and between the back gate electrode BG and the second active pattern AP2.

The first word line WL1 and the second word line WL2 may be disposed on the data storage pattern DSP. The first word line WL1 and the second word line WL2 may be disposed on the contact patterns BC. The data storage patterns DSP may be disposed between the first word line WL1 and the substrate 100. The data storage patterns DSP may be disposed between the second word line WL2 and the substrate 100.

Each of the first word line WL1 and the second word line WL2 may extend in the second direction DR2. The first word line WL1 and the second word line WL2 may be arranged alternately in the first direction DR1.

The first word line WL1 and the second word line WL2 may be spaced apart from the bit line BL and the contact pattern BC in the third direction DR3. The first word line WL1 and the second word line WL2 may be located between the bit line BL and the contact pattern BC.

The first word line WL1 and the second word line WL2 may include a conductive material. The first word line WL1 and the second word line WL2 may include, for example, at least one of a doped polysilicon, a conductive metal nitride, a conductive metal silicon nitride, a metal carbonitride, a conductive metal silicide, a conductive metal oxide, a two-dimensional material, and a metal.

The gate insulating film may be disposed between the first word line WL1 and the first active pattern AP1, and between the second word line WL2 and the second active pattern AP2.

A first bit line BL1 may be disposed on the first active pattern AP1 and the second active pattern AP2. The first bit line BL1 may be connected to the first active pattern AP1 and the second active pattern AP2.

The first bit line BL1 may be disposed on the back gate electrode BG, the first word line WL1, and the second word line WL2. The first bit line BL1 may extend in the first direction DR1 across the back gate electrode BG.

The first bit line BL1 includes a conductive material, and may include, for example, at least one of a doped polysilicon, a conductive metal nitride, a conductive metal silicon nitride, a metal carbonitride, a conductive metal silicide, a conductive metal oxide, a two-dimensional material, and a metal.

A shielding conductive pattern SL may be disposed on the first bit line BL1. The first bit line BL1 may be disposed between the shielding conductive pattern SL and the first word line WL1. The first bit line BL1 may be disposed between the shielding conductive pattern SL and the second word line WL2.

For example, the shielding conductive pattern SL may include a shielding conductive plate and a plurality of shielding conductive protrusions. The shielding conductive plate may have a flat plate shape. The plurality of shielding conductive protrusions may protrude from the shielding conductive plate in the third direction DR3. The shielding conductive protrusion may be disposed between the first bit lines BL1 adjacent to each other in the second direction DR2.

The shielding conductive pattern SL includes a conductive material, and may include at least one of, for example, a conductive metal nitride, a conductive metal silicon nitride, a metal carbonitride, a conductive metal silicide, a conductive metal oxide, a two-dimensional material, and a metal.

Unlike the shown example, the shielding conductive pattern SL may not include a flat shielding conductive plate. For example, the shielding conductive pattern SL may include a plurality of shielding conductive protrusions having a linear shape.

The data storage pattern DSP is shown as being disposed between the substrate 100 and the first bit line BL1, but is not limited thereto. Unlike the illustrated example, the data storage pattern DSP may be disposed between the peri-active substrate 200 and the first bit line BL1. In this case, the first bit line BL1 may be disposed between the substrate 100 and the word lines WL1 and WL2.

In the semiconductor memory device according to some embodiments, the first bit line BL1, the first word line WL1, and the second word line WL2 may be disposed between the substrate 100 and the peri-active substrate 200.

A first lower insulating film 271, a second lower insulating film 272, and a third lower insulating film 273 may be sequentially disposed on the substrate 100. The data storage pattern DSP may be disposed inside the first lower insulating film 271. The contact pattern BC may be disposed inside the second lower insulating film 272. The first and second word lines WL1 and WL2, the first bit line BL1, and the shielding conductive pattern SL may be disposed inside the third lower insulating film 273.

The first lower insulating film 271, the second lower insulating film 272, and the third lower insulating film 273 may include an insulating material. Although the first lower insulating film 271, the second lower insulating film 272, and the third lower insulating film 273 are depicted as single layers for simplicity of explanation, this should not be construed as limiting the scope of the embodiment.

A lower contact plug 243a and a lower wiring line 243b may be disposed inside the third lower insulating film 273. The lower wiring line 243b may be disposed on the data storage pattern DSP, the first bit line BL1, the first word line WL1, and the second word line WL2. In particular, the lower contact plug 243a may contact the first and second word lines WL1 and WL2.

The lower contact plug 243a may connect the lower wiring line 243b to the word lines WL1 and WL2. The lower contact plug 243a may connect the lower wiring line 243b to the shielding conductive pattern SL. In particular, the lower contact plug 243a may contact the shielding conductive pattern SL. Additionally, the lower contact plug 243a may connect the lower wiring line 243b to the first bit line BL1. The lower contact plug 243a may also connect the lower wiring line 243b to the plate electrode 255 of the data storage pattern DSP.

The lower contact plug 243a and the lower wiring line 243b are shown as being different films, but are not limited thereto. The boundary between the lower contact plug 243a and the lower wiring line 243b may be indistinguishable or continuous. Each of the lower contact plug 243a and the lower wiring line 243b includes a conductive material.

The first connecting wiring structure 261 may be disposed on the lower wiring line 243b. The first connecting wiring structure 261 may be connected to the lower wiring line 243b. The first connecting wiring structure 261 may be disposed inside the third lower insulating film 273.

The first connecting wiring structure 261 may include a first connecting wiring 261b and a first connecting via 261a. The first connecting wiring structure 261 is shown as including a single first connecting wiring 261b located on one metal level for ease of explanation; however, this is not a limitation of the embodiment. Alternatively, the first connecting wiring structure 261 may include a plurality of first connecting wirings 261b positioned on different metal levels.

The first connecting wiring 261b and the first connecting via 261a may each include a conductive material. The first connecting wiring 261b and the first connecting via 261a are depicted as different films; however, this is not a limitation of the embodiment.

The peri-active substrate 200 may be disposed on the first connecting wiring structure 261. In particular, the peri-active substrate 200 may be disposed on the third lower insulating film 273. The peri-active substrate 200 may be spaced apart from the substrate 100 in the third direction DR3. The first connecting wiring structure 261 may be disposed between the substrate 100 and the peri-active substrate 200.

The peri-active substrate 200 includes a peri-semiconductor film 200SL and a peri-semiconductor separation film 200SI. For example, the peri-active substrate 200 may include a plurality of peri-semiconductor separation films 200SI. As will be discussed later, the peri-active substrate 200 allows for advanced vertical stacking, significantly enhancing spatial utilization and electrical performance.

The peri-semiconductor film 200SL includes a semiconductor material. The peri-semiconductor film 200SL may include, but is not limited to, silicon, silicon germanium, indium antimonide, lead telluride, indium arsenide, indium phosphide, gallium arsenide or gallium antimonide. In the following description, the peri-semiconductor film 200SL will be described as a silicon film including silicon.

The peri-semiconductor separation film 200SI includes an insulating material. In the semiconductor memory device according to some embodiments, the peri-semiconductor separation film 200SI may include a first peri-semiconductor separation liner 200SI_A, a second peri-semiconductor separation liner 200SI_B, and a peri-semiconductor separation filling film 200SI_C. The first peri-semiconductor separation liner 200SI_A, the second peri-semiconductor separation liner 200SI_B, and the peri-semiconductor separation filling film 200SI_C may be sequentially arranged.

The first peri-semiconductor separation liner 200SI_A may be disposed on the peri-semiconductor film 200SL. In particular, the first peri-semiconductor separation liner 200SI_A may contact the peri-semiconductor film 200SL. For example, the first peri-semiconductor separation liner 200SI_A may extend in the third direction DR3.

The second peri-semiconductor separation liner 200SI_B may be disposed on the first peri-semiconductor separation liner 200SI_A. In particular, the second peri-semiconductor separation liner 200SI_B may contact the first peri-semiconductor separation liner 200SI_A. The first peri-semiconductor separation liner 200SI_A may be disposed between the second peri-semiconductor separation liner 200SI_B and the peri-semiconductor film 200SL.

The peri-semiconductor separation filling film 200SI_C may be disposed on the second peri-semiconductor separation liner 200SI_B. In particular, the peri-semiconductor separation filling film 200SI_C may contact the second peri-semiconductor separation liner 200SI_B. The second peri-semiconductor separation liner 200SI_B may be disposed between the first peri-semiconductor separation liner 200SI_A and the peri-semiconductor separation filling film 200SI_C.

For example, each of the first peri-semiconductor separation liner 200SI_A and the peri-semiconductor separation filling film 200SI_C may include silicon oxide. The second peri-semiconductor separation liner 200SI_B may include silicon nitride. However, the materials described for the first peri-semiconductor separation liner 200SI_A, the second peri-semiconductor separation liner 200SI_B, and the peri-semiconductor separation filling film 200SI_C are provided as examples and not intended to limit the embodiment.

The peri-active substrate 200 may include a first surface 200_S1 and a second surface 200_S2 that are opposite to each other in the third direction DR3. The second surface 200_S2 of the peri-active substrate 200 may face the substrate 100 and the first connecting wiring structure 261. In other words, the second surface 200_S2 of the peri-active substrate 200 is closer to the substrate 100 and the first connecting wiring structure 261 than the first surface 200_S1 of the peri-active substrate 200.

Both the first surface 200_S1 and the second surface 200_S2 of the peri-active substrate 200 includes a peri-semiconductor film 200SL and a peri-semiconductor separation film 200SI. In other words, the peri-semiconductor film 200SL and the peri-semiconductor separation film 200SI define the first surface 200_S1 and the second surface 200_S2 of the peri-active substrate 200.

The peri-semiconductor film 200SL may include a first surface 200SL_S1 and a second surface 200SL_S2 that are opposite to each other in the third direction DR3. The peri-semiconductor separation film 200SI may include a first surface 200SI_S1 and a second surface 200SI_S2 that are opposite to each other in the third direction DR3.

The first surface 200_S1 of the peri-active substrate 200 may include a first surface 200SL_S1 of the peri-semiconductor film 200SL and a first surface 200SI_S1 of the peri-semiconductor separation film 200SI. The first surface 200SL_S1 of the peri-semiconductor film 200SL may be the first surface 200_S1 of the peri-active substrate 200 defined by the peri-semiconductor film 200SL. The first surface 200SI_S1 of the peri-semiconductor separation film 200SI may be the first surface 200_S1 of the peri-active substrate 200 defined by the peri-semiconductor separation film 200SI.

The second surface 200_S2 of the peri-active substrate 200 may include the second surface 200SL_S2 of the peri-semiconductor film 200SL and the second surface 200SI_S2 of the peri-semiconductor separation film 200SI. The second surface 200SL_S2 of the peri-semiconductor film 200SL may be the second surface 200_S2 of the peri-active substrate 200 defined by the peri-semiconductor film 200SL. The second surface 200SI_S2 of the peri-semiconductor separation film 200SI may be the second surface 200_S2 of the peri-active substrate 200 defined by the peri-semiconductor separation film 200SI.

For example, in a cross-sectional view, the second surface 200SI_S2 of the peri-semiconductor separation film 200SI may be flat. In the semiconductor memory device according to some embodiments, the first surface 200SI_S1 of the peri-semiconductor separation film 200SI may have a convex shape, such as a convex curved surface. As will be discussed later, the convex-shape of the peri-semiconductor separation film 200SI, which is a result of the fabrication process, ensures precise alignment and improved contact reliability with overlying components, such as the peri-gate structure PG and wiring layers. This shape not only enhances structural integrity but also minimizes parasitic effects, leading to superior device performance.

Since the first surface 200SI_S1 of the peri-semiconductor separation film 200SI has a convex shape, a part of the peri-semiconductor separation film 200SI may protrude beyond the first surface 200SL_S1 of the peri-semiconductor film 200SL. A thickness H1 of the peri-semiconductor separation film 200SI in the third direction DR3 may be greater than a thickness H2 of the peri-semiconductor film 200SL in the third direction DR3.

A width W11 of the first surface 200SI_S1 of the peri-semiconductor separation film 200SI in the second direction DR2 may be greater than a width W12 of the second surface 200SI_S2 of the peri-semiconductor separation film 200SI in the second direction DR2. In other words, the peri-semiconductor separation film 200SI on the first surface 200_S1 of the peri-active substrate 200 has a greater width in the second direction DR2 than on the second surface 200_S2 of the peri-active substrate 200.

The width of the first surface 200SI_S1 of the peri-semiconductor separation film 200SI in the first direction DR1 may be greater than the width of the second surface 200SI_S2 of the peri-semiconductor separation film 200SI in the first direction DR1.

A peri-element separation film 210 may be disposed inside the peri-semiconductor film 200SL. The peri-element separation film 210 may be formed on the first surface 200SL_S1 of the peri-semiconductor film 200SL.

The peri-element separation film 210 does not extend to the second surface 200SL_S2 of the peri-semiconductor film 200SL. A thickness H3 of the peri-element separation film 210 in the third direction DR3 is smaller than the thickness H1 of the peri-semiconductor separation film 200SI in the third direction DR3.

The peri-element separation film 210 may include a first surface 210_S1 that is not covered with the peri-semiconductor film 200SL. The first surface 210_S1 of the peri-element separation film may be an exposed surface that is not covered with the peri-semiconductor film 200SL. In other words, the first surface 210_S1 serves as an exposed surface, remaining uncovered by the peri-semiconductor film 200SL.

The width of the peri-element separation film 210 in the second direction DR2 may decrease as it goes away from the first surface 200SL_S1 of the peri-semiconductor film 200SL. The width W21 of the first surface 210_S1 of the peri-element separation film 210 in the second direction DR2 may represent the width of the peri-element separation film 210 in the second direction DR2. The width W11 of the first surface 200SI_S1 of the peri-semiconductor separation film 210 in the second direction DR2 corresponds to the width of the peri-semiconductor separation film 200SI in the second direction DR2. For example, the width W21 of the peri-element separation film 210 in the second direction DR2 is smaller than the width W11 of the peri-semiconductor separation film 200SI in the second direction DR2.

The peri-element separation film 210 includes an insulating material. For example, the peri-element separation film 210 may include a first peri-element separation liner 210A, a second peri-element separation liner 210B, and a peri-element separation filling film 210C. The first peri-element separation liner 210A, the second peri-element separation liner 210B, and the peri-element separation filling film 210C may be arranged in sequence.

The first peri-element separation liner 210A may be disposed between the second peri-element separation liner 210B and the peri-semiconductor film 200SL. For example, the first peri-element separation liner 210A may be in contact with both the second peri-element separation liner 210B and the peri-semiconductor film 200SL. The second peri-element separation liner 210B may be disposed between the first peri-element separation liner 210A and the peri-element separation filling film 210C. For example, the second peri-element separation liner 210B may be in contact with the first peri-element separation liner 210A and the peri-element separation filling film 210C.

For example, each of the first peri-element separation liner 210A and the peri-element separation filling film 210C may include silicon oxide. The second peri-element separation liner 210B may include silicon nitride. However, the description of the materials used for the first peri-element separation liner 210A, the second peri-element separation liner 210B, and the peri-element separation filling film 210C is provided as an example and is not intended to be limiting.

In an alternative configuration, the peri-element separation film 210 may include the second peri-element separation liner 210B and the peri-element separation filling film 210C, omitting the first peri-element separation liner 210A.

The peri-gate structure PG may be disposed on the peri-semiconductor film 200SL. The peri-gate structure PG may be disposed on the first surface 200_S1 of the peri-active substrate 200. The peri-gate structure PG may be disposed on the first surface 200SL_S1 of the peri-semiconductor film 200SL. The peri-gate structure PG may be included in a sensing transistor, a transfer transistor, a driving transistor, etc.

The peri-gate structure PG may include a peri-gate insulating film 215 and a peri-gate conductive film 225. The peri-gate insulating film 215 may include a silicon oxide film, a silicon oxynitride film, a high dielectric constant insulating film having a higher dielectric constant than the silicon oxide film, or a combination thereof. The high dielectric constant insulating film may include, but is not limited to, at least one of, for example, metal oxide, metal oxynitride, metal silicon oxide, and metal silicon oxynitride.

The peri-gate conductive film 225 may include a conductive material. The peri-gate conductive film 225 may include, but is not limited to, at least one of, for example, a doped semiconductor material, a conductive metal nitride, a conductive metal silicon nitride, a metal carbonitride, a conductive metal silicide, a conductive metal oxide, a two-dimensional material (2D material), and a metal. In the semiconductor memory device according to some embodiments, the 2D material may be a metallic material and/or a semiconductor material. The 2D material may include a 2D allotrope or a 2D compound, and may include, for example, but is not limited to, at least one of graphene, molybdenum disulfide (MoS₂), molybdenum diselenide (MoSe₂), tungsten diselenide (WSe₂), and tungsten disulfide (WS₂). That is, since the above-mentioned 2D materials mentioned above are provided as examples, and the 2D materials that may be included in the semiconductor memory device of the present disclosure are not to those listed.

Additionally, a peri-gate spacer may be disposed on the side wall of the peri-gate structure PG. The peri-gate spacer includes an insulating material. In addition, the peri-gate structure PG may further include a peri-gate mask pattern disposed on the peri-gate conductive film 225. The peri-gate mask pattern is made of an insulating material.

A peri-source/drain region 230 may be disposed on both sides of the peri-gate structure PG. The peri-source/drain region 230 may be formed inside the peri-semiconductor film 200SL. For example, the peri-source/drain region 230 may be formed near the first surface 200SL_S1 of the peri-semiconductor film 200SL.

As an example, the peri-source/drain region 230 may be an impurity-doped region in which an n-type or p-type impurity element is doped inside the peri-semiconductor film 200SL. As another example, the peri-source/drain region 230 may include an epitaxial semiconductor pattern. The epitaxial semiconductor pattern may be formed, using an epitaxial growth method. The epitaxial semiconductor pattern may include a doped n-type or p-type impurity element. The n-type impurity element may include at least one of phosphorus (P), arsenic (As), antimony (Sb) and bismuth (Bi). The p-type impurity element may include at least one of boron (B) and gallium (Ga).

A peri-etching stop film 205 may extend along the first surface 200_S1 of the peri-active substrate 200. The peri-etching stop film 205 may extend along the profile of the peri-gate structure PG. In other words, the peri-etching stop film 205 may conform to and extend along the profile of the peri-gate structure PG.

The peri-etching stop film 205 may include an insulating material having an etching selectivity with respect to an upper insulating film 281.

The upper insulating film 281 is disposed on the first surface 200_S1 of the peri-active substrate 200. The upper insulating film 281 is disposed on the peri-etching stop film 205. The upper insulating film 281 includes an insulating material. Although the upper insulating film 281 is shown as being a single film, this is for convenience of explanation, and the embodiment is not limited thereto.

The peri-contact plug 241a and the peri-wiring line 241b may be disposed inside the upper insulating film 281.

The peri-contact plug 241a may be connected to the peri-source/drain region 230. The peri-contact plug 241a may be connected to the peri-gate structure PG. The peri-contact plug 241a may be connected to the peri-gate conductive film 225 of the peri-gate structure PG. For example, the peri-contact plug 241a may penetrate the peri-etching stop film 205, and may be connected to the peri-source/drain region 230 and the peri-gate conductive film 225.

The peri-wiring line 241b may be disposed on the peri-contact plug 241a and the peri-gate structure PG. The peri-wiring line 241b may be disposed on the first surface 200_S1 of the peri-active substrate 200. The peri-wiring line 241b is connected to the peri-contact plug 241a. For example, the peri-wiring line 241b may be a wiring line that is closest to the peri-gate structure PG in the third direction DR3.

The peri-contact plug 241a and the peri-wiring line 241b are depicted as separate layer for illustrative purposes; however, this is not a limitation of the embodiment. The boundary between the peri-contact plug 241a and the peri-wiring line 241b may be continuous. Each of the peri-contact plug 241a and the peri-wiring line 241b includes a conductive material.

The peri-connecting penetration plug 242 may be disposed between the peri-wiring line 241b and the first connecting wiring structure 261. The peri-connecting penetration plug 242 may pass through the upper insulating film 281, the peri-active substrate 200 and the third lower insulating film 273. The peri-connecting penetration plug 242 may connect the peri-wiring line 241b and the first connecting wiring structure 261. For example, the peri-connecting penetration plug 242 may connect the peri-wiring line 241b and the first connecting wiring 261b.

The peri-connecting penetration plug 242 may penetrate the peri-semiconductor separation film 200SI. The peri-connecting penetration plug 242 may penetrate the peri-etching stop film 205.

The peri-connecting penetration plug 242 includes a conductive material.

The second connecting wiring structure 262 may be disposed on the peri-wiring line 241b. The second connecting wiring structure 262 may be connected to the peri-wiring line 241b. The second connecting wiring structure 262 may be disposed inside the upper insulating film 281.

The second connecting wiring structure 262 may include a second connecting wiring 262b and a second connecting via 262a. The second connecting wiring structure 262 is depicted as including a plurality of second connecting wirings 262b positioned at different metal levels for simplicity of explanation; however, this is not intended to limit the embodiment.

The second connecting wirings 262b and the second connecting via 262a may each include a conductive material. The second connecting wirings 262b and the second connecting via 262a are depicted as separate layers for illustrative purposes; however, this is not intended to limit the embodiment.

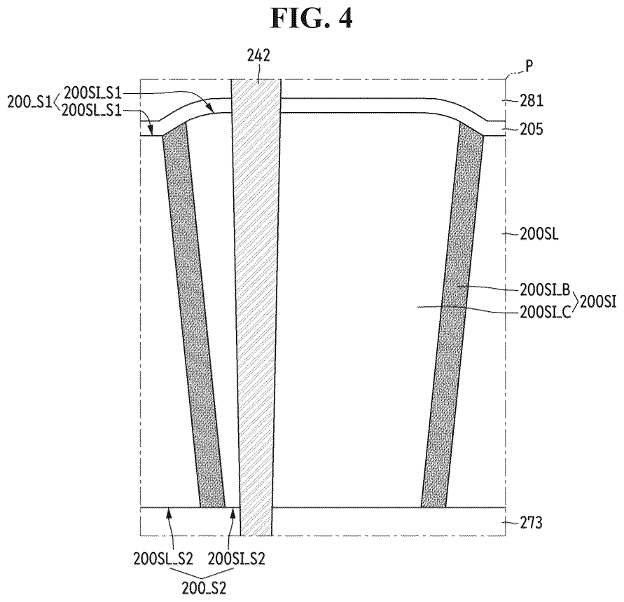

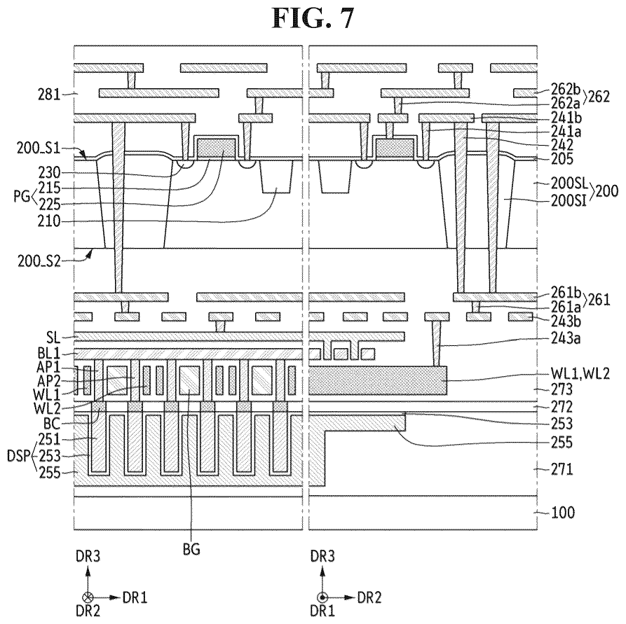

FIGS. 4 to 6 are diagrams for explaining a semiconductor memory device according to some embodiments. FIG. 7 is a diagram for explaining a semiconductor memory device according to some embodiments. For convenience of explanation, the discussion will primarily focus on differences from the descriptions provided in FIGS. 1 to 3.

For reference, FIGS. 4 to 6 are diagrams showing an enlarged view of a portion P of FIG. 1.

Referring to FIG. 4, in the semiconductor memory device according to some embodiments, the peri-semiconductor separation film 200SI may include a second peri-semiconductor separation liner 200SI_B and a peri-semiconductor separation filling film 200SI_C.

In this embodiment, the first peri-semiconductor separation liner (200SI_A of FIG. 2) may not be disposed between the peri-semiconductor film 200SL and the second peri-semiconductor separation liner 200SI_B.

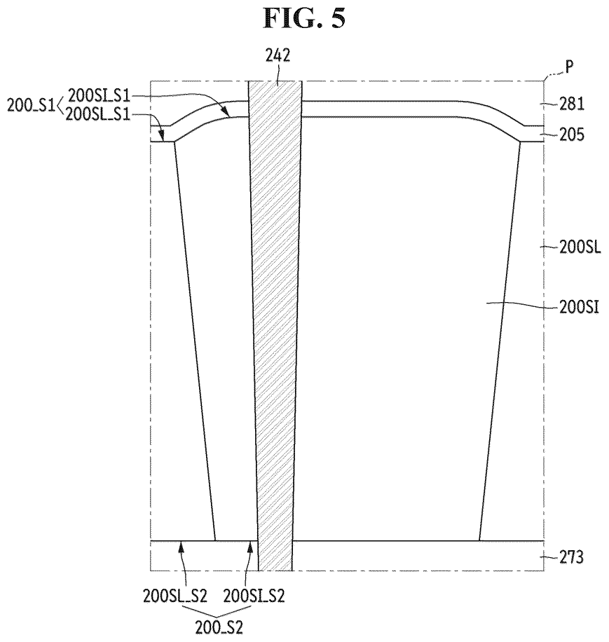

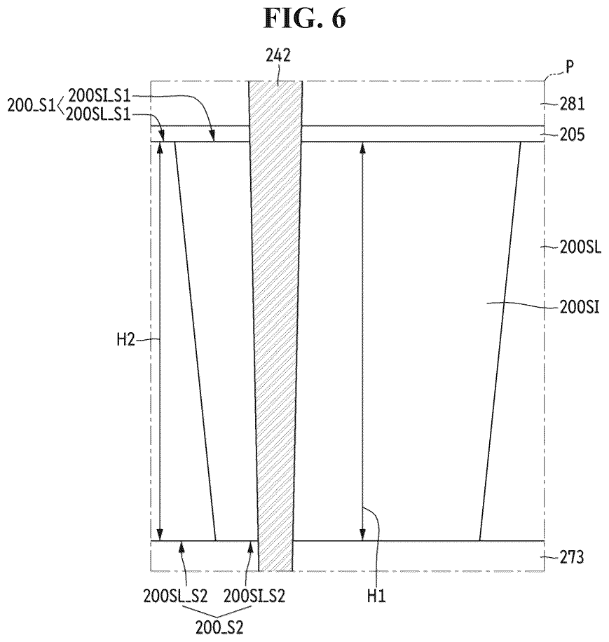

Referring to FIGS. 5 and 6, in the semiconductor memory device according to some embodiments, the peri-semiconductor separation film 200SI may have a single film structure.

For example, the peri-semiconductor separation film 200SI may have a single insulating film structure formed of silicon oxide.

In FIG. 5, from a cross-sectional perspective, the first surface 200SI_S1 of the peri-semiconductor separation film 200SI may have a convex shape.

In FIG. 6, from a cross-sectional perspective, the first surface 200SI_S1 of the peri-semiconductor separation film 200SI may be flat. The thickness H1 of the peri-semiconductor separation film 200SI in the third direction DR3 may be identical to the thickness H2 of the peri-semiconductor film 200SL in the third direction DR3.

In FIG. 7, in the semiconductor memory device according to some embodiments, a plurality of peri-connecting penetration plugs 242 may penetrate the peri-semiconductor separation film 200SI. The plurality of peri-connecting penetration plugs 242 may be used to connect different peri-wiring lines 241b to the first connecting wiring 261b.

The peri-active substrate 200 may include a first peri-semiconductor separation film 200SI and a second peri-semiconductor separation film 200SI. The first peri-semiconductor separation film 200SI may be spaced apart from the second peri-semiconductor separation film 200SI in the second direction. For example, one peri-connecting penetration plug 242 may penetrate the first peri-semiconductor separation film 200SI. A plurality of peri-connecting penetration plugs 242 may penetrate the second peri-semiconductor separation film 200SI.

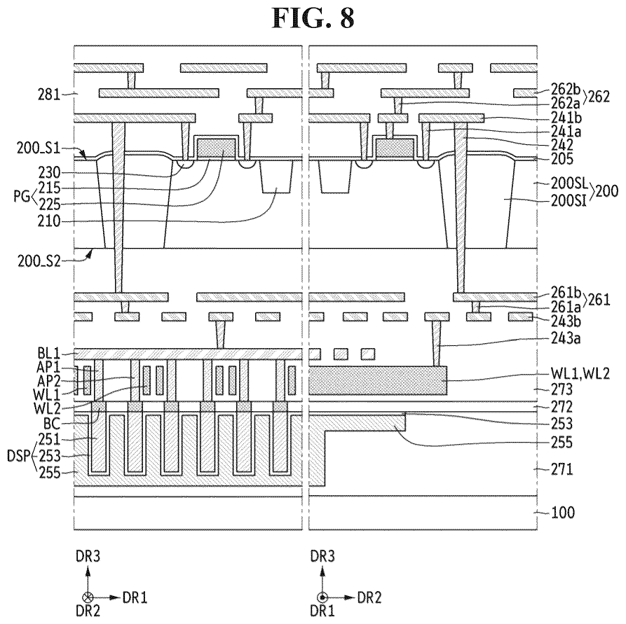

FIG. 8 is a diagram for explaining a semiconductor memory device according to some embodiments. For ease of explanation, the discussion will primarily focus on differences from the descriptions provided in FIGS. 1 to 3.

Referring to FIG. 8, the semiconductor memory device according to some embodiments may not include a back gate electrode (BG of FIG. 1).

For example, a back gate electrode (BG of FIG. 1) may not be disposed between the first active pattern AP1 and the second active pattern AP2 that are adjacent to each other in the first direction DR1.

For example, the first active pattern AP1 and the second active pattern AP2 may include an oxide semiconductor material. The first active pattern AP1 and the second active pattern AP2 may include, for example, a metal oxide. As an example, the first active pattern AP1 and the second active pattern AP2 may be an amorphous metal oxide film. As another example, the first active pattern AP1 and the second active pattern AP2 may be a polycrystalline metal oxide film. As yet another example, the first active pattern AP1 and the second active pattern AP2 may include a combination of an amorphous metal oxide film and a polycrystalline metal oxide film. As yet another example, the first active pattern AP1 and the second active pattern AP2 may be a c-axis aligned crystalline (CAAC) metal oxide film.

The first active pattern AP1 and the second active pattern AP2 may include, for example, but are not limited to, at least one of indium oxide, tin oxide, zinc oxide, In—Zn-based oxide (IZO), Sn—Zn-based oxide, Al—Zn-based oxide, Zn—Mg-based oxide, Sn—Mg-based oxide, In—Mg-based oxide, In—Ga-based oxide (IGO), In—Ga—Zn-based oxide (IGZO), In—Al—Zn-based oxide, In—Sn—Zn-based oxide, Sn—Ga—Zn-based oxide, Al—Ga—Zn-based oxide, Sn—Al—Zn-based oxide, In—Hf—Zn-based oxide, In—La—Zn-based oxide, In—Ce—Zn-based oxide, In—Pr—Zn-based oxide, In—Nd—Zn-based oxide, In—Sm—Zn-based oxide, In—Eu—Zn-based oxide, In—Gd—Zn-based oxide, In—Tb—Zn-based oxide, In—Dy—Zn-based oxide, In—Ho—Zn-based oxide, In—Er—Zn-based oxide, In—Tm—Zn-based oxide, In—Yb—Zn-based oxide, In—Lu—Zn-based oxide, In—Sn—Ga—Zn-based oxide, In—Hf—Ga—Zn-based oxide, In—Al—Ga—Zn-based oxide, In—Sn—Al—Zn-based oxide, In—Sn—Hf—Zn-based oxide, and In—Hf—Al—Zn-based oxide.

Here, the In—Ga—Zn-based oxide refers to an oxide that has In, Ga, and Zn as main components, but does not refer to a ratio of In, Ga, and Zn. In other words, using IGZO (indium gallium zinc oxide) as an example, the first active pattern AP1 and the second active pattern AP2 may include IGZO (indium gallium zinc oxide, InₓGa_{y}Zn_{z}O). The IGZO (In:Ga:Zn=1:1:1) containing indium, gallium and zinc at the same ratio may be an In—Ga—Zn-based oxide. A Ga-rich IGZO may have a higher ratio of gallium than the IGZO (In:Ga:Zn=1:1:1), and a lower ratio of indium than the IGZO (In:Ga:Zn=1:1:1). The Ga-rich IGZO may also be an In-Ga-Zn-based oxide. An In-rich IGZO may also have a higher ratio of indium than IGZO (In:Ga:Zn=1:1:1) and a lower ratio of gallium than IGZO (In:Ga:Zn=1:1:1). The In-rich IGZO may also be an In—Ga—Zn-based oxide.

Although the above description references IGZO, the embodiment is not limited to this material. It is worth noting that the description also applies when the first active pattern AP1 and the second active pattern AP2 include a ternary or higher-order metal oxide. Additionally, the first active pattern AP1 and the second active pattern AP2 may further include a doped metal element other than In, Ga, and Zn, when the first active pattern AP1 and the second active pattern AP2 include the In-Ga-Zn-based oxide.

Although the shielding conductive pattern (SL of FIG. 1) is not shown in FIG. 8, the embodiment is not limited thereto. For example, the shielding conductive pattern SL may be disposed between the first bit lines BL1 adjacent to each other in the second direction DR2.

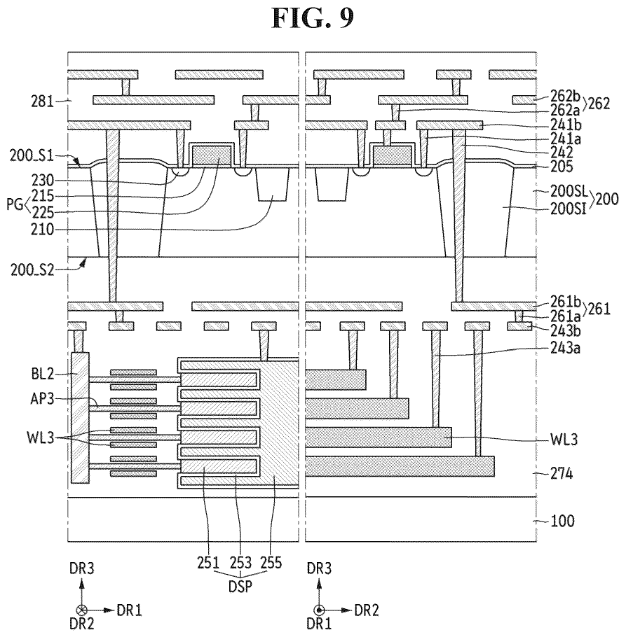

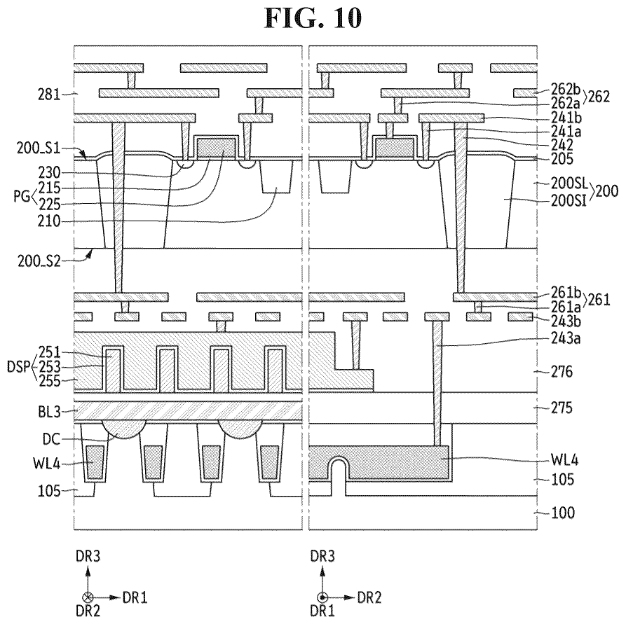

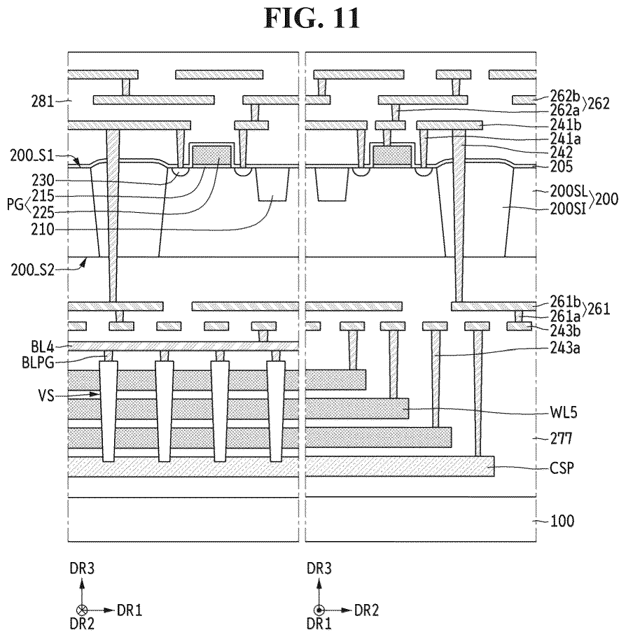

FIG. 9 is a diagram for explaining a semiconductor memory device according to some embodiments. FIG. 10 is a diagram for explaining a semiconductor memory device according to some embodiments. FIG. 11 is a diagram for explaining a semiconductor memory device according to some embodiments. For ease of explanation, the discussion will primarily focus on the differences from those described in FIGS. 1 to 3.

Referring to FIG. 9, the semiconductor memory device according to some embodiments may include a third active pattern AP3, a third word line WL3, and a second bit line BL2.

A plurality of third active patterns AP3 may be disposed on the substrate 100. Each of the third active patterns AP3 may extend lengthwise in the first direction DR1.

The plurality of third active patterns AP3 may be stacked in the third direction DR3. Each of the third active patterns AP3 may be spaced apart from each other in the third direction DR3. The third active pattern AP3 may include a silicon pattern.

The third word line WL3 may extend in the second direction DR2. Each of the third word lines WL3 may be spaced apart from each other in the third direction DR3.

The third word line WL3 may surround the third active pattern AP3. For example, one third word line WL3 may surround the plurality of third active patterns AP3 disposed at the same height level.

In a cross-sectional view along the second direction DR2, the third word lines WL3 stacked in the third direction DR3 may exhibit a stepped shape. The third word lines WL3 include a conductive material.

The second bit line BL2 may be connected to one end of each third active pattern AP3. In other words, the second bit line BL2 may be connected to a first end of each third active pattern AP3. The second bit line BL2 may be connected to the plurality of third active patterns AP3 stacked in the third direction DR3.

The second bit line BL2 may extend in the third direction DR3. Adjacent second bit lines BL2 may be spaced apart from each other in the second direction DR2. The second bit line BL2 includes a conductive material.

The data storage pattern DSP may be connected to the other end of each third active pattern AP3. In other words, the data storage pattern DSP may be connected to a second end of each third active pattern AP3. The second end of the third active pattern AP3 is spaced apart from the first end of the third active pattern AP3 in the first direction DR1. The storage electrodes 251 may be connected to the respective third active patterns AP3.

A fourth lower insulating film 274 may be disposed on the substrate 100. The data storage pattern DSP, the second bit line BL2, the third word line WL3, and the third active pattern AP3 may be disposed inside the fourth lower insulating film 274.

The fourth lower insulating film 274 may include an insulating material. Although the fourth lower insulating film 274 is depicted as a single layer for simplicity of explanation, this is not intended to limit the embodiment.

The lower contact plug 243a may connect the lower wiring line 243b to the third word line WL3. The lower contact plug 243a may connect the lower wiring line 243b to the second bit line BL2. The lower contact plug 243a may connect the lower wiring line 243b to the plate electrode 255 of the data storage pattern DSP. The lower contact plug 243a may be in direct contact with each of the third word line WL3, the second bit line BL2 and the data storage pattern DSP.

The lower contact plug 243a, the lower wiring line 243b, and the first connecting wiring structure 261 may be disposed inside the fourth lower insulating film 274.

Referring to FIG. 10, the semiconductor memory device according to some embodiments may include a fourth word line WL4 and a third bit line BL3.

A cell element separation film 105 may be disposed inside the substrate 100. The cell element separation film 105 may define a cell active region. The cell element separation film 105 may include an insulating material.

The fourth word line WL4 may be disposed inside the substrate 100 and the cell element separation film 105. The fourth word line WL4 may extend in the second direction DR2. The fourth word lines WL4 may be spaced apart from each other in the first direction DR1.

The third bit line BL3 may be disposed on the substrate 100 and the cell element separation film 105. The third bit line BL3 may be disposed on the fourth word line WL4.

The third bit line BL3 may extend in the first direction DR1. The third bit lines BL3 may be spaced apart from each other in the second direction DR2.

A direct contact DC may be disposed between the third bit line BL3 and the substrate 100. The direct contact DC may be connected to a cell active region of the substrate 100. The direct contact DC may connect the third bit line BL3 to the cell active region.

Each of the fourth word line WL4, the third bit line BL3, and the direct contact DC may include a conductive material.

The data storage pattern DSP may be disposed on the third bit line BL3. The third bit line BL3 may be disposed between the fourth word line WL4 and the data storage pattern DSP.

A fifth lower insulating film 275 and a sixth lower insulating film 276 may be disposed on the substrate 100. The third bit line BL3 may be disposed inside the fifth lower insulating film 275. The data storage pattern DSP may be disposed inside the sixth lower insulating film 276.

The fifth lower insulating film 275 and the sixth lower insulating film 276 may include an insulating material. Although the fifth lower insulating film 275 and the sixth lower insulating film 276 are shown as being single films for simplicity of explanation, the embodiment is not limited thereto.

The lower contact plug 243a may connect the lower wiring line 243b and the fourth word line WL3. The lower contact plug 243a may connect the lower wiring line 243b and the plate electrode 255 of the data storage pattern DSP. The lower contact plug 243a may also connect the lower wiring line 243b and the third bit line BL3.

The lower contact plug 243a, the lower wiring line 243b, and the first connecting wiring structure 261 may be disposed inside the sixth lower insulating film 276.

Referring to FIG. 11, the semiconductor memory device according to some embodiments may include a common source line CSP, a fifth word line WL5, a memory channel structure VS, and a fourth bit line BL4.

The common source line CSP may have a plate shape. The common source line CSP includes a conductive material.

A plurality of fifth word lines WL5 may be disposed on the common source line CSP. In a cross-sectional view along the second direction DR2, the third word line WL3, stacked in the third direction DR3, may exhibit a stepped configuration. Each fifth word line WL5 may extend in the second direction DR2. The fifth word line WL5 includes a conductive material.

The memory channel structure VS may penetrate the plurality of fifth word lines WL5. The memory channel structure VS may include a channel region and a charge storage region. The channel region of the memory channel structure VS may be electrically connected to the common source line CSP.

The fourth bit line BL4 may be disposed on the memory channel structure VS. The fourth bit line BL4 may extend in the first direction DR1. The fourth bit line BL4 may be electrically connected to the channel region of the memory channel structure VS.

A bit line plug BLPG may be disposed between the fourth bit line BL4 and the memory channel structure VS. The bit line plug BLPG may connect the fourth bit line BL4 to the memory channel structure VS. Each of the fourth bit line BL and the bit line plug BLPG includes a conductive material.

A seventh lower insulating film 277 may be disposed on the substrate 100. The fourth bit line BL4 and the fifth word line WL5 may be disposed inside the seventh lower insulating film 277.

The seventh lower insulating film 277 may include an insulating material. Although the seventh lower insulating film 277 is shown as being a single film for convenience of explanation, the embodiment is not limited thereto.

The lower contact plug 243a may connect the lower wiring line 243b to the fifth word line WL5. The lower contact plug 243a may connect the lower wiring line 243b to the fourth bit line BL4.

The lower contact plug 243a, the lower wiring line 243b, and the first connecting wiring structure 261 may be disposed inside the seventh lower insulating film 277.

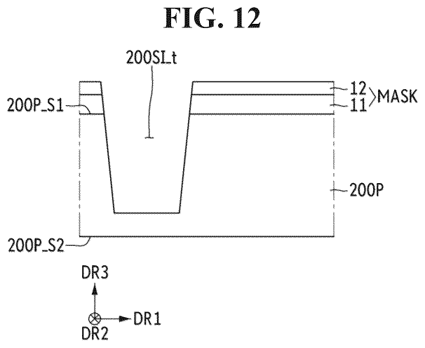

FIGS. 12 to 21 are intermediate stage diagrams for describing a method for manufacturing a semiconductor memory device according to some embodiments.

For reference, FIGS. 12 to 19 show cross-sectional views taken in the first direction DR1 in FIG. 1. The cross-sectional views taken in the second direction DR2 in FIG. 1 may be substantially identical to those shown in FIGS. 12 to 19.

Referring to FIG. 12, a mask pattern MASK may be formed on a pre-substrate 200P.

The pre-substrate 200P may include a first surface 200P_S1 and a second surface 200P_S2 that are opposite to each other in the third direction DR3. The mask pattern MASK may be formed on the first surface 200P_S1 of the pre-substrate 200P.

The mask pattern MASK may include a lower mask pattern 11 and an upper mask pattern 12. The lower mask pattern 11 may include, for example, silicon oxide. The upper mask pattern 12 may include, for example, silicon nitride.

The mask pattern MASK may be used as an etching mask to form a substrate separation trench 200SI_t. The substrate separation trench 200SI_t may be formed inside the pre-substrate 200P. A bottom surface of the substrate separation trench 200SI_t may be defined by the pre-substrate 200P.

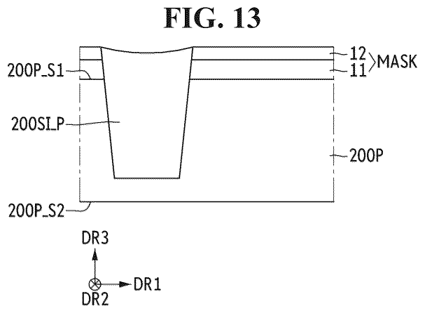

Referring to FIGS. 12 and 13, a first pre-semiconductor separation film 200SI_P may be formed inside the substrate separation trench 200SI_t.

The first pre-semiconductor separation film 200SI_P may fill the substrate separation trench 200SI_t. The first pre-semiconductor separation film 200SI_P is shown as a single film; however, this is not a limitation of the embodiment. For example, the first pre-semiconductor separation film 200SI_P may have a double-film or triple-film structure as shown in FIGS. 2 and 4.

The upper surface of the first pre-semiconductor separation film 200SI_P is shown to have a concave shape; however, this is not a limitation of the embodiment. Alternatively, the upper surface of the first pre-semiconductor separation film 200SI_P may be flat.

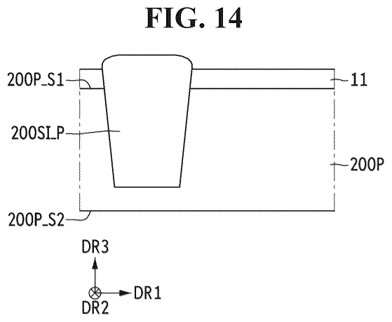

Referring to FIGS. 13 and 14, the upper mask pattern 12 may be removed.

During the removal of the upper mask pattern 12, a portion of the first pre-semiconductor separation film 200SI_P may be etched. For instance, after the upper mask pattern 12 is removed, the upper surface of the first pre-semiconductor separation film 200SI_P may take on a convex shape. In this state, the first pre-semiconductor separation film 200SI_P may protrude above the upper surface of the lower mask pattern 11. This convex shape can be subsequently used to enhance alignment precision and improve the structural integrity of the semiconductor memory device.

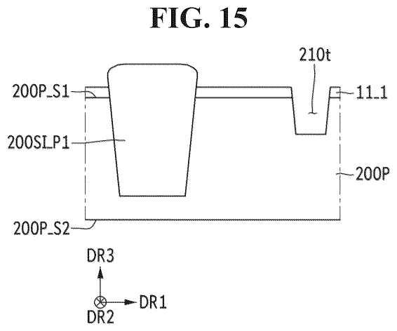

Referring to FIGS. 14 and 15, an element separation film trench 210t may be formed inside the pre-substrate 200P.

While the element separation film trench 210t is being formed, a part of the first pre-semiconductor separation film 200SI_P may be etched to form a second pre-semiconductor separation film 200SI_P1.

Additionally, while the element separation film trench 210t is being formed, a part of the lower mask pattern 11 may be removed to form a lower mask residual film 11_1. The lower mask residual film 11_1 may be formed due to a decrease in the thickness of the lower mask pattern 11.

A part of the second pre-semiconductor separation film 200SI_P1 may protrude beyond an upper surface of the lower mask residual film 11_1.

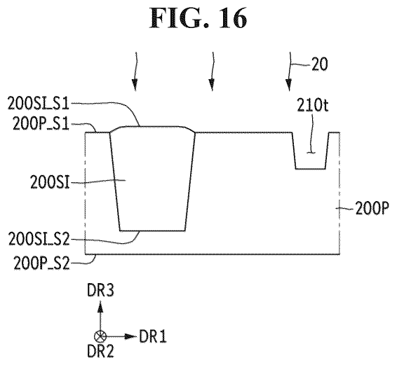

Referring to FIGS. 15 and 16, the lower mask residual film 11_1 may be removed, using a cleaning process 20.

The cleaning process 20 may etch and remove the lower mask residual film 11_1. While the lower mask residual film 11_1 is being removed, the second pre-semiconductor separation film 200SI_P1 protruding beyond the first surface 200P_S1 of the pre-substrate 200P may be removed. Accordingly, the peri-semiconductor separation film 200SI may be formed inside the substrate separation trench 200SI_t.

The first surface 200SI_S1 of the peri-semiconductor separation film 200SI may have a convex shape. Since the first surface 200SI_S1 of the peri-semiconductor separation film 200SI is convex, it enhances alignment precision and improves the structural integrity of the semiconductor memory device. Unlike the shown example, the first surface 200SI_S1 of the peri-semiconductor separation film 200SI may be flat.

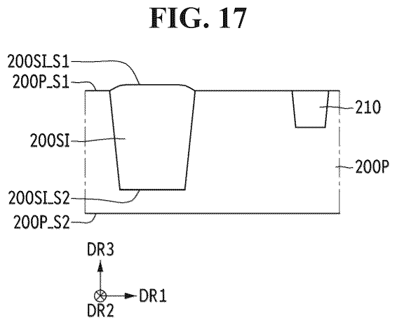

Referring to FIGS. 16 and 17, the peri-element separation film 210 may be formed inside the element separation film trench 210t.

The peri-element separation film 210 may fill the element separation film trench 210t. The peri-element separation film 210 may have a multi-layer film structure including a plurality of insulating films as shown in FIG. 3.

Since the first surface 200SI_S1 of the peri-semiconductor separation film 200SI does not have a concave shape, the insulating films that form the peri-element separation film 210 are not formed inside the substrate separation trench 200SI_t.

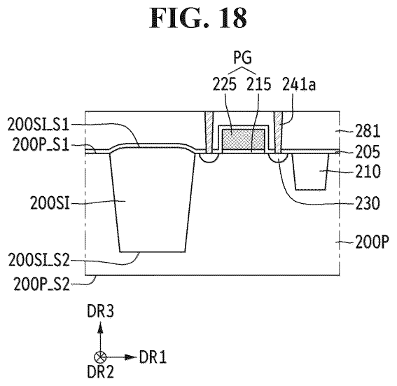

Referring to FIG. 18, the peri-gate structure PG may be formed on the first surface 200P_S1 of the pre-substrate 200P.

The peri-source/drain region 230 may be formed inside the pre-substrate 200P. The peri-source/drain region 230 may be formed on both sides of the peri-gate structure PG.

Next, the peri-etching stop film 205 may be formed along the first surface 200P_S1 of the pre-substrate 200P and the first surface 200SI_S1 of the peri-semiconductor separation film 200SI. The peri-etching stop film 205 may be formed along the profile of the peri-gate structure PG.

The upper insulating film 281 may be formed on the peri-etching stop film 205. Next, the peri-contact plug 241a may be formed. The peri-contact plug 241a may be formed inside the upper insulating film 281.

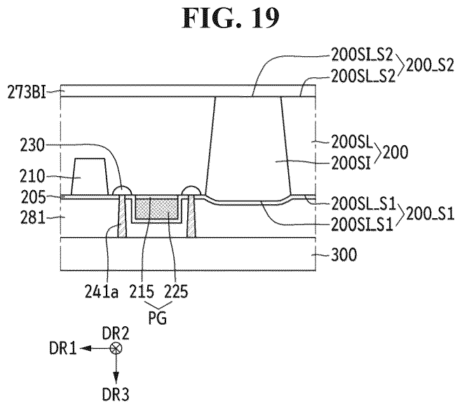

Referring to FIGS. 18 and 19, the pre-substrate 200P on which the peri-gate structure PG is formed may be bonded to a supporting substrate 300.

The upper insulating film 281 may be located between the supporting substrate 300 and the pre-substrate 200P.

Next, a part of the pre-substrate 200P may be removed to expose the peri-semiconductor separation film 200SI. Accordingly, the peri-semiconductor film 200SL may be formed. A peri-active substrate 200 including the peri-semiconductor separation film 200SI and the peri-semiconductor film 200SL may be formed on the supporting substrate 300. This structure allows for advanced vertical stacking, significantly enhancing spatial utilization and electrical performance.

Next, a bonding insulating film 273BI may be formed on the second surface 200_S2 of the peri-active substrate.

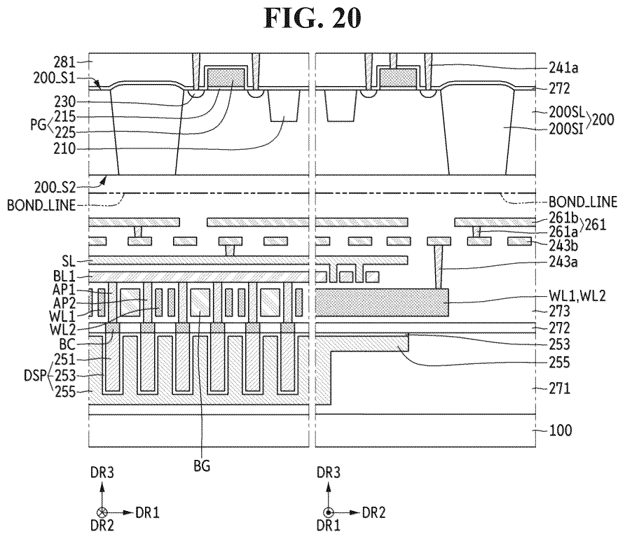

Referring to FIGS. 19 and 20, a substrate 100 having the data storage pattern DSP formed thereon may be bonded to the supporting substrate 300.

The substrate 100 may be bonded to the supporting substrate 300, using the bonding insulating film 273BI. The bonding insulating film 273BI may be a part of a third lower insulating film 273. The third lower insulating film 273 located above the bonding line BOND_LINE may be the bonding insulating film 273BI.

After the substrate 100 and the supporting substrate 300 are bonded, the supporting substrate 300 may be removed.

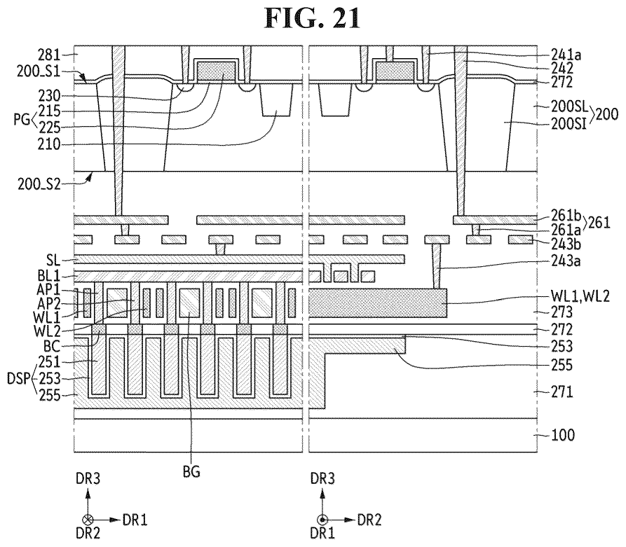

Referring to FIG. 21, a peri-connecting penetration plug 242 which penetrates the peri-semiconductor separation film 200SI may be formed.

The peri-connecting penetration plug 242 may be connected to the first connecting wiring structure 261.

Referring next to FIG. 1, a peri-wiring line 241b may be formed on the peri-contact plug 241a and the peri-connecting penetration plug 242. A second connecting wiring structure 262 may be formed on the peri-wiring line 241b.

In conclusion, those skilled in the art will recognize that various modifications and adjustments can be made to the embodiments without departing significantly from the principles of the present disclosure. Accordingly, the embodiments described herein are provided for illustrative purposes and should not be construed as limiting the scope of the disclosure.

What is claimed is:

1. A semiconductor memory device comprising:
a peri-active substrate which includes a peri-semiconductor film and a peri-semiconductor separation film, wherein the peri-active substrate overlaps a substrate in a first direction;
a first connecting wiring structure which is disposed between the substrate and the peri-active substrate;
a peri-gate structure which is disposed on the peri-semiconductor film;
a peri-contact plug which is connected to the peri-gate structure;
a peri-wiring line which is connected to the peri-contact plug; and
a peri-connecting penetration plug which penetrates the peri-semiconductor separation film, and connects the first connecting wiring structure and the peri-wiring line,
wherein the peri-active substrate includes a first surface and a second surface that are opposite to each other in the first direction,
each of the first surface of the peri-active substrate and the second surface of the peri-active substrate is formed by the peri-semiconductor film and the peri-semiconductor separation film,
the peri-wiring line and the peri-gate structure are disposed on the first surface of the peri-active substrate, and
the first surface of the peri-active substrate formed by the peri-semiconductor separation film is convex.

2. The semiconductor memory device of claim 1, further comprising:
a peri-element separation film which is disposed inside the peri-semiconductor film,
wherein a thickness of the peri-element separation film in the first direction is less than a thickness of the peri-semiconductor separation film in the first direction.

3. The semiconductor memory device of claim 2,
wherein a width of the peri-element separation film in a second direction is less than a width of the peri-semiconductor separation film in the second direction.

4. The semiconductor memory device of claim 2,
wherein the peri-semiconductor separation film is a single film, and
the peri-element separation film includes a peri-element separation liner, and a peri-element separation filling film on the peri-element separation liner.

5. The semiconductor memory device of claim 1, further comprising:
a peri-etching stop film which extends along the first surface of the peri-active substrate,
wherein the peri-connecting penetration plug penetrates the peri-etching stop film.

6. The semiconductor memory device of claim 1,
wherein a width of the peri-semiconductor separation film in a second direction on the first surface of the peri-active substrate is greater than a width of the peri-semiconductor separation film in the second direction on the second surface of the peri-active substrate.

7. The semiconductor memory device of claim 1,
wherein the second surface of the peri-active substrate formed by the peri-semiconductor separation film is flat.

8. The semiconductor memory device of claim 1,
wherein the peri-semiconductor separation film includes a peri-semiconductor separation liner, and a peri-semiconductor separation filling film on the peri-semiconductor separation liner.

9. The semiconductor memory device of claim 1,
wherein the peri-semiconductor separation film is a single film.

10. The semiconductor memory device of claim 1, further comprising:
a second connecting wiring structure which is disposed on the peri-wiring line, and connected to the peri-wiring line.

11. The semiconductor memory device of claim 1, further comprising:
a word line and a bit line which are disposed between the substrate and the peri-active substrate.

12. A semiconductor memory device comprising:
a peri-active substrate which includes a peri-semiconductor film and a peri-semiconductor separation film, wherein the peri-active substrate overlaps a substrate in a first direction;
a connecting wiring structure which is disposed between the substrate and the peri-active substrate;
a peri-gate structure which is disposed on the peri-semiconductor film;
a peri-contact plug which is connected to the peri-gate structure;
a peri-wiring line which is connected to the peri-contact plug; and
a peri-connecting penetration plug which penetrates the peri-semiconductor separation film, and connects the connecting wiring structure and the peri-wiring line,
wherein the peri-active substrate includes a first surface and a second surface that are opposite to each other in the first direction,
each of the first surface of the peri-active substrate and the second surface of the peri-active substrate is formed by the peri-semiconductor film and the peri-semiconductor separation film, and
a thickness of the peri-semiconductor separation film in the first direction is greater than a thickness of the peri-semiconductor film in the first direction.

13. The semiconductor memory device of claim 12,
wherein the first surface of the peri-active substrate formed by the peri-semiconductor separation film is convex.

14. The semiconductor memory device of claim 12, further comprising:
a peri-element separation film which is disposed inside the peri-semiconductor film.

15. The semiconductor memory device of claim 14,
wherein a width of the peri-element separation film in a second direction is less than a width of the peri-semiconductor separation film in the second direction, and
a thickness of the peri-element separation film in the first direction is less than the thickness of the peri-semiconductor separation film in the first direction.

16. The semiconductor memory device of claim 12,
wherein the peri-semiconductor separation film is a single film.

17. The semiconductor memory device of claim 12,
wherein the peri-semiconductor separation film includes a peri-semiconductor separation liner, and a peri-semiconductor separation filling film on the peri-semiconductor separation liner.

18. The semiconductor memory device of claim 12, further comprising:
a word line and a bit line which are disposed between the substrate and the peri-active substrate.

19. A semiconductor memory device comprising:
a peri-active substrate, which is spaced apart from a substrate in a first direction, and includes a peri-semiconductor film and a peri-semiconductor separation film, a thickness of the peri-semiconductor separation film in the first direction being greater than a thickness of the peri-semiconductor film in the first direction;
a peri-element separation film which is disposed inside the peri-semiconductor film;
a data storage pattern which is disposed between the substrate and the peri-active substrate;
a connecting wiring structure which is disposed between the substrate and the peri-active substrate, and connected to the data storage pattern;
a peri-gate structure which is disposed on the peri-semiconductor film;
a peri-contact plug which is connected to the peri-gate structure;
a peri-wiring line which is connected to the peri-contact plug; and
a peri-connecting penetration plug which penetrates the peri-semiconductor separation film, and connects the connecting wiring structure and the peri-wiring line,
wherein the peri-active substrate includes a first surface and a second surface that are opposite to each other in the first direction,
the peri-wiring line and the peri-gate structure are disposed on the first surface of the peri-active substrate,
the first surface of the peri-active substrate formed by the peri-semiconductor separation film is convex,
a thickness of the peri-element separation film in the first direction is less than the thickness of the peri-semiconductor separation film in the first direction, and
a width of the peri-element separation film in a second direction is less than a width of the peri-semiconductor separation film in the second direction.

20. The semiconductor memory device of claim 19,
wherein each of the first surface of the peri-active substrate and the second surface of the peri-active substrate includes the peri-semiconductor film and the peri-semiconductor separation film.
